(19) United States
(12) Patent Application Publication
(10) Pub. No.: US 2005/0281128 A1
(43) Pub. Date: Dec. 22, 2005

(54) Semiconductor memory apparatus and method for operating a semiconductor memory apparatus

(76) Inventor: Jean-Marc Dortu, Munchen (DE)

Correspondence Address: GERO G. McCLELLAN;MOSER, PATTERSON & SHERIDAN, L.L.P., Suite 1500, 3040 Post Oak Blvd., Houston, TX, 77056, US

(21) Appl. No.: 10/993,003

(22) Filed: Nov. 19, 2004

(30) Foreign Application Priority Data
Nov. 19, 2003 (DE) DE 103 54 034.2

(51) Int. Cl. G11C 8/00

(52) U.S. Cl. 365/233

(57) ABSTRACT

One embodiment of the invention provides a method for operating a semiconductor memory apparatus, comprising the following steps: providing a first timer signal; providing a second timer signal which is independent of the first timer signal; providing a data validation signal which can assume at least a first value and a second value, wherein the data validation signal assumes the first value when data transfer from and/or to the semiconductor memory apparatus is not taking place, and the data validation signal assumes the second value when data transfer from and/or to the semiconductor memory apparatus is taking place; transferring a write command to the semiconductor memory apparatus in sync with the first timer signal; in response to the received write command, setting the data validation signal to assume the second value; and reading-in data in sync with the second timer signal while the data validation signal is set to the second value. Another embodiment of the invention provides a semiconductor memory apparatus for performing the method.

### CROSS-REFERENCE TO RELATED APPLICATIONS

This application claims foreign priority benefits under 35 U.S.C. §119 to co-pending German patent application number DE 103 54 034.2, filed 19 Nov. 2003. This related patent application is herein incorporated by reference in its entirety.

### BACKGROUND OF THE INVENTION

1. Field of the Invention

The present invention relates to a method for operating a semiconductor memory apparatus and to a semiconductor memory apparatus.

2. Description of the Related Art

A signal diagram showing signal profiles based on the prior art when data are written to a semiconductor memory apparatus is shown in FIG. 2. In this context, a write command (CMD “W”) is initiated in sync with an external timer or clock signal CK. After a particular period of time t_{DQSS}, a DQS signal changes to a “low” state. In this context, the DQS signal is the signal which is used to write data to the semiconductor memory apparatus. After a predetermined period of time, the number of edges of the DQS signal which are required for writing data is generated. In the present example, the burst length is four bits and the data in one burst need to be transferred. Hence, four rising and falling edges are needed for the data transfer.

The “write latency” WL is the period of time or the number of clock cycles between the write command and the time at which the first data bit is read in, assuming that the data are centered around the clock signal CK (FIG. 2).

An important timing parameter in this context is the time t_{DQSS}, which defines the degree of freedom for the DQS signal with respect to the timer signal CK. This period of time is the period of time between the edge of the timer signal CK used to initiate the write command and the first active edge of the DQS signal. In this context, the problem arises that the first edge of the DQS signal can be generated only with a certain level of inaccuracy on account of reflections on the transfer path (shown by A in FIG. 2). The time t_{DQSS} is normally stipulated such that the following equation is satisfied:
t_{DQSS}=WL±0.25 TCK
where TCK is the period duration of the clock signal. In addition, t_{DQSS} becomes smaller and smaller the higher the clock rate at which the semiconductor memory apparatus is operated. In particular, t_{DQSS} is dependent on the propagation times of the signals on the semiconductor memory apparatus and on external conditions, such as the process used, the voltage applied and the prevailing ambient temperature. Hence, t_{DQSS} is a limiting factor for operating the semiconductor memory apparatus at high frequencies. With increasingly higher operating frequencies, it thus becomes increasingly difficult to satisfy the above equation for t_{DQSS}.

Therefore, there is a need to provide a method for operating a semiconductor memory apparatus and a semiconductor memory apparatus which provide a simple way of safely operating the semiconductor memory apparatus, particularly at high clock rates.

### SUMMARY OF THE INVENTION

One embodiment of the invention provides a method for operating a semiconductor memory apparatus, comprising the following steps:

providing a first timer signal or clock signal;

providing a second timer signal or clock signal which is substantially independent of the first timer signal;

providing a data validation signal or data valid signal which can assume at least a first value and a second value, wherein
the data validation signal assumes the first value when data transfer from and/or to the semiconductor memory apparatus is not taking place, and
the data validation signal assumes the second value when data transfer from and/or to the semiconductor memory apparatus is taking place;

transferring a write command to the semiconductor memory apparatus in sync with the first timer signal;

setting the data validation signal so that it assumes the second value;

reading-in data in sync with the second timer signal while the data validation signal is set to the second value.

The data validation signal may assume the first value when no write operation is to be performed. Setting the data validation signal means that the value of the data validation signal changes from the first value to the second value.

Within the context of this invention, “in sync” means that an event is carried out or occurs on a rising or falling edge of a clock signal.

Using the method described above, a second timer signal, which is essentially independent of the first timer signal, is used to latch incoming data which are intended to be written to the semiconductor memory apparatus, or to write them to the semiconductor memory apparatus bit by bit in sync with the second timer signal. In particular, the t_{DQSS} timing can be relaxed by a factor of approximately 2.

By providing a continuous second timer signal, it is possible to increase the accuracy of the placement of the edges of the timer signal or to increase the clock edge placement accuracy.

The method may also comprise the following steps:

buffer-storing a predetermined number of data items which have been read in, and

transferring the buffer-stored data in parallel to the memory cells within the semiconductor memory apparatus.

The predetermined number of data items which have been read in, which is buffer-stored, may correspond to the burst length prescribed for the respective semiconductor memory apparatus.

In one embodiment, the parallel transfer is carried out in sync with the first timer signal. Carrying out the parallel transfer in sync with the first timer signal effects a transition or a change from the time domain of the second timer signal to the time domain of the first timer signal. The first timer signal may be a command and/or address timer signal or command/address clock, and the second timer signal may be a data timer signal or data latching clock. The path profile of the second timer signal may be the same as that of the corresponding data line. Hence, the propagation times of the second timer signal and of the transferred data bits are essentially the same.

The data validation signal may be set and reset in sync with the second timer signal. In particular, resetting the data validation signal means that the data validation signal changes from the second value to the first value. The data may be read in on the rising and falling edges of the second timer signal.

In one embodiment, the second timer signal is an essentially constant signal when the data validation signal has not been set to the second value.

In one embodiment, the method also comprises the following steps:

setting the data validation signal so that it assumes the second value; and

outputting data in sync with the second timer signal while the data validation signal is set to the second value.

Hence, in line with one embodiment of the present invention, in addition to writing data to the semiconductor memory apparatus, the data validation signal may also be used to read data from the semiconductor memory apparatus.

One embodiment of the invention also provides a semiconductor memory apparatus, particularly for use in the method according to embodiments of the present invention, comprising a multiplicity of contacts or connections or pins, wherein the contacts comprise:

a first timer signal contact, which is designed to receive a first timer signal;

a second timer signal contact, which is designed to receive a second timer signal, which is essentially independent of the first timer signal;

a data validation signal contact, which is designed to receive a data validation signal which can assume at least a first value and a second value, wherein
the data validation signal assumes the first value when data transfer from and/or to the semiconductor memory apparatus is not taking place, and
the data validation signal assumes the second value when data transfer from and/or to the semiconductor memory apparatus is taking place;

at least one command contact, which is at least designed to receive a write command to the semiconductor memory apparatus in sync with the first timer signal;

at least one data contact, which is designed to receive or to read in data in sync with the second timer signal while the data validation signal has the second value.

### BRIEF DESCRIPTION OF THE DRAWINGS

Further features, aspects and advantages of the present invention become obvious from the detailed description of a preferred embodiment with reference to the drawings, in which:

FIG. 1 shows a signal diagram showing the profile of a plurality of signals while the method based on a preferred embodiment of the present invention is carried out;

FIG. 2 shows a signal diagram showing the profile of signals when the method based on the prior art is carried out; and

FIG. 3 is a block diagram of a semiconductor memory apparatus according to one embodiment of the invention.

### DETAILED DESCRIPTION OF THE PREFERRED EMBODIMENT

In one embodiment of the present invention, a semiconductor memory apparatus 30, as shown in FIG. 3, is provided which comprises a plurality of contacts, connections or pins. The contacts comprise a first timer signal contact or system clock contact 31 (or pin), which is designed to receive a first timer signal or a system clock CK, and a second timer signal contact 32 (or data latching clock contact), which is designed to receive a second timer signal DK, which is essentially independent of the first timer signal. In addition, the contacts comprise a data validation signal contact 33, which is designed to receive a data validation signal DVLD which can assume at least a first value, e.g., “low” or “0”, and a second value, e.g., “high” or “1”. The data validation signal DVLD assumes the first value when data transfer from and/or to the semiconductor memory apparatus is not taking place, and the data validation signal DVLD assumes the second value when data transfer is taking place. In addition, at least one command contact 34ₙ is provided, which is at least designed to receive a write command “W” to the semiconductor memory apparatus in sync with the first timer signal CK, and at least one data contact 35ₙ is provided, which is designed to receive or to read in data or data bits D0 to D3 in sync with the second timer signal DK while the data validation signal DVLD has the second value.

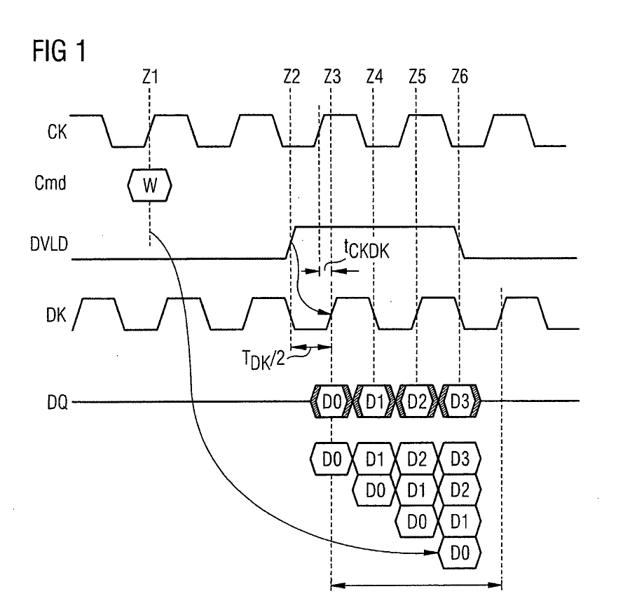

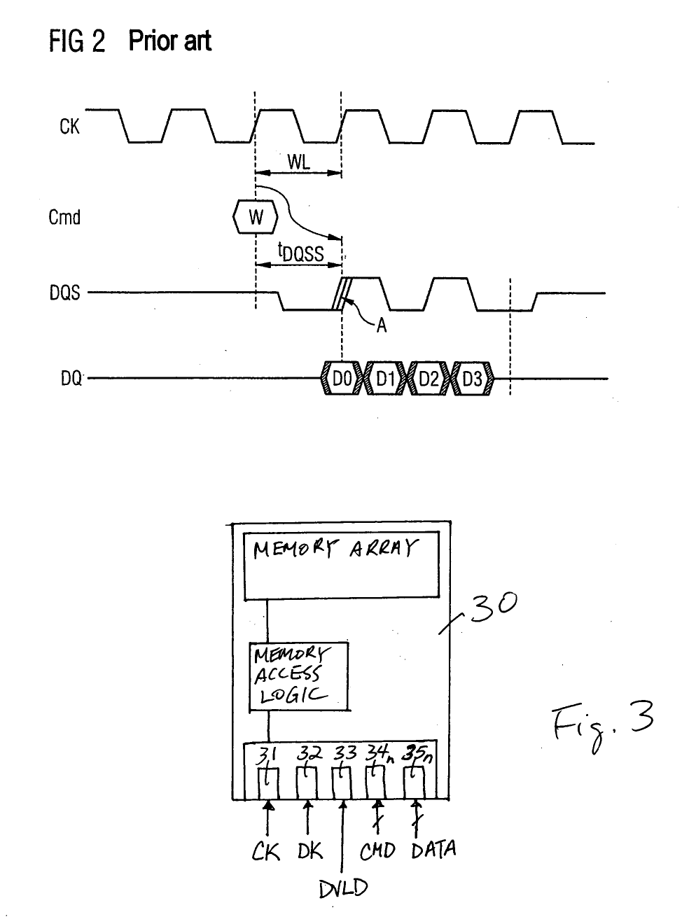

One embodiment of the inventive method is described in detail below with reference to FIG. 1. The method described below is intended to be used, in particular, to write data to a semiconductor memory apparatus.

In FIG. 1, the signal CK represents the signal profile of a first timer signal or of the system clock or of the command and address timer. The signal CMD shows the profile of a command signal, such as a write command “write” or a read command “read” , which are or can be transferred to the semiconductor memory apparatus. The signal profile DVLD is the signal profile of a data validation signal which may be used to write and/or read data or to read out data.

The signal profile DK represents the signal profile of a second timer signal or of a data clock or of a data timer signal or of a data latching clock. The DK signal is essentially independent of the CK signal and is shifted by the value t_{CKDK} with respect to the CK signal. The signal profile DQ shows the data bits D0 to D3 which have been read in, which are intended to be written to the semiconductor memory apparatus.

In the description below, times shown in FIG. 1 are respectively identified by Z and a subsequent digit.

A write command “W” is transferred to the semiconductor memory apparatus in sync with a rising edge of the CK clock signal (time Z1). After a predetermined period of time, the DVLD signal is brought or set from a first value or “low” to a second value or “high” in sync with the DK clock signal (time Z2). When the DVLD signal has assumed the second value, the receivers in the semiconductor memory apparatus are ready to receive data. Data can be received while the DVLD signal has the second value. The DVLD signal may be set half a period duration T_{DK}/2 of the DK clock signal before the first data bit D0 is transferred.

Subsequently, data bits D0 to D3 of a burst length are read in in sync with the DK clock signal (times Z3 to Z6). In the example shown in FIG. 1, the length of a burst is four bits. Alternatively, however, provision may be made for the length of or number of bits in a burst to have a different value. For example, the length of a burst may be eight bits. The data bits D0 to D3 may be respectively latched or read in on the rising and falling edges of the DK signal. The data which have been read in are buffer-stored and, when all of the bits D0 to D3 in a burst have been read in, these data bits D0 to D3 are transferred in parallel.

The parallel transfer of the data bits D0 to D3 is carried out in sync with the CK clock signal. There is thus a transition or a change to the CK time domain. In one embodiment, there may be two clock periods available for the parallel transfer of the data.

When the data bits D0 to D3 have been read in, the DVLD signal is reset again or changes from the second value to the first value or “low”. In the embodiment shown, this is done in sync with the edge of the DK signal on which the last data bit D3 is read in (time Z6). However, it is likewise conceivable to provide a different timing for the DVLD signal.

Providing the DK signal which is essentially independent of the CK signal improves the positioning of the edges of the clock signal for the data transfer in comparison with the prior art. In particular, the time difference between the first edge of the DK signal used for data transfer and a corresponding edge of the CK signal is essentially dependent on the time shift between the two signals.

The data bits D0 to D3 are read in or latched in the DK time domain or in sync with the DK signal. Subsequently, the data are transferred to the CK time domain in parallel. The time domains are thus decoupled. The timer signal used to read in data bits is essentially independent of reflections on the transfer path. Hence, the temporal relationship between the timer signal DK used to read in the data and the data can be determined more precisely. In comparison with the prior art, it is thus possible to provide tighter or shorter timing for reading in the data bits. The margin or the required latitude or the required additional period of time which needs to be provided on account of inaccuracies in the signals can be reduced.

In addition to the embodiment described above, provision may be made for the DVLD signal likewise to be used when data are read from the semiconductor memory apparatus (not shown in FIG. 1). The data are read out in line with the data being written. In this case, the DVLD signal is used bidirectionally in order to allow both writing to and reading from the semiconductor memory apparatus.

While the foregoing is directed to embodiments of the present invention, other and further embodiments of the invention may be devised without departing from the basic scope thereof, and the scope thereof is determined by the claims that follow.

1. A method for operating a semiconductor memory apparatus, comprising:
providing a first timer signal;
providing a second timer signal which is independent of the first timer signal;
providing a data validation signal which can assume at least a first value and a second value, wherein
the data validation signal assumes the first value when data transfer from and/or to the semiconductor memory apparatus is not taking place, and
the data validation signal assumes the second value when data transfer from and/or to the semiconductor memory apparatus is taking place;
transferring a write command to the semiconductor memory apparatus in sync with the first timer signal while the data validation signal is at the first value;
in response to the received write command, setting the data validation signal to assume the second value; and
reading-in data in sync with the second timer signal while the data validation signal is set to the second value.

2. The method of claim 1, further comprising:
buffer-storing a predetermined number of data items which have been read in; and
transferring the buffer-stored data items in parallel to memory cells within the semiconductor memory apparatus.

3. The method of claim 2, wherein the parallel transfer is carried out in sync with the first timer signal.

4. The method of claim 1, wherein the first timer signal is one of a command timer signal and an address timer signal.

5. The method of claim 1, wherein the second timer signal is a data timer signal.

6. The method of claim 1, wherein the data validation signal is set and reset in sync with the second timer signal.

7. The method of claim 1, wherein the data are read in on rising and falling edges of the second timer signal.

8. The method of claim 1, wherein the second timer signal is a constant signal.

9. The method of claim 1, further comprising:
setting the data validation signal to assume the second value in response to a read command; and
outputting data in sync with the second timer signal while the data validation signal is set to the second value.

10. A method for operating a memory device, comprising:
receiving a data transfer command in sync with a first clock signal;
in response to the received data transfer command, setting a data validation signal to enable data transfer to and from the memory device; and
transferring data in sync with a second clock signal which is independent of the first clock signal while the data validation signal is set to enable data transfer.

11. The method of claim 10, wherein the data transfer command is a read command and the data is output from the memory device in sync with the second clock signal.

12. The method of claim 10, wherein the data transfer command is a write command and the data is read-in in sync with the second clock signal.

13. The method of claim 12, further comprising:
buffering a predetermined items of the read-in data; and
transferring the buffered items in parallel to memory cells of the memory device.

14. The method of claim 13, wherein the parallel transfer is carried out in sync with the first clock signal.

15. The method of claim 10, wherein the first clock signal is one of a system clock and a command and address timer.

16. The method of claim 15, wherein the second clock signal is a data timer signal.

17. The method of claim 16, wherein the data validation signal is set and reset in sync with the second timer signal.

18. The method of claim 16, wherein the data are read in on rising and falling edges of the second timer signal.

19. The method of claim 16, wherein the second timer signal is a constant signal.

20. A semiconductor memory apparatus, comprising a plurality of contacts, wherein the contacts comprise:
a first timer signal contact configured to receive a first timer signal;
a second timer signal contact configured to receive a second timer signal which is independent of the first timer signal;
a data validation signal contact configured to receive a data validation signal which can assume at least a first value and a second value, wherein
the data validation signal assumes the first value when data transfer from and/or to the semiconductor memory apparatus is not taking place, and
the data validation signal assumes the second value when data transfer from and/or to the semiconductor memory apparatus is taking place;
at least one command contact configured to receive at least a write command to the semiconductor memory apparatus in sync with the first timer signal; and
at least one data contact, which is designed to receive data in sync with the second timer signal while the data validation signal has the second value.
